(19) United States
(12) Patent Application Publication
(10) Pub. No.: US 2006/0258058 A1
(43) Pub. Date: Nov. 16, 2006

(54) Surface-mounted device with leads

(75) Inventor: Bernd Offermann, Hamburg (DE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLILKE PHILIPS ELECTRONICS N.V., Eindhoven (NL)

(21) Appl. No.: 10/569,217

(22) PCT Filed: Aug. 17, 2004
(86) PCT No.: PCT/IB04/51467

§ 371 Date: Feb. 23, 2006

(30) Foreign Application Priority Data
Aug. 27, 2003 (EP) 03102663.6

(51) Int. Cl. H01L 21/00; H01L 23/52

(52) U.S. Cl. 438/127; 257/784

(57) ABSTRACT

A surface-mounted device comprising a semiconductor chip (5) encapsulated in a package (1) and leads (2) projecting from the package so as to bring the semiconductor chip into contact with a substrate (3), which leads are provided at their surface, at the location of one of the pads provided for surface mounting, with a three-dimensional contact pattern.

The invention relates to a surface-mounted device comprising a semiconductor chip encapsulated in a package, and leads projecting from the package for bringing the semiconductor chip into contact with a substrate. The invention relates, in particular, to a flat-pack surface-mounted device.

According to the state of the art, discrete semiconductor devices and integrated circuits in the form of surface-mounted devices, customarily abbreviated as SMD, are soldered directly onto the superficial interconnect layer of substrates, for example printed circuit boards and ceramic substrates.

To protect the semiconductor chips from undesirable mechanical and chemical influences and to conduct away and distribute dissipated heat, said semiconductor chips are customarily encapsulated in a package of synthetic resin, ceramic or metal. Only the external connections in the form of a plurality of projecting leads are led out of the package. Via the leads the semiconductor chip encased in the package is connected, both electrically and mechanically, with the printed circuit board on which components are to be inserted.

Such surface-mounted devices with a package are customarily manufactured such that a semiconductor chip is connected, for example by using adhesive or solder, to a lead frame, i.e. a support comprising the leads. The pads of the semiconductor chip are subsequently connected to the associated metallic lead frame surfaces by means of gold wires.

After said “wire bonding”, the semiconductor chip together with the gold wires and the adjoining regions of the lead frame are encapsulated using an isolating molded compound, in such a manner that a so-termed “package” is formed from which the leads project laterally.

In the case of conventional packages, the end portion of the leads, which is not embedded in the package, is bent substantially parallel to the bearing surface, so that, during assembly on a printed circuit board, the end portion of the leads rests flat on the printed circuit board and can be soldered there.

For the assembly of surface-mounted semiconductor elements use is commonly made, particularly in automated production processes, of so-termed SM-solder methods (surface-mount methods).

In this assembly process, the leads are initially provisionally attached to solder connection spots on the printed circuit board, after which they are soldered in a special, fully automatic soldering process. SM soldering processes include condensation soldering, infrared soldering, double-wave soldering, etc.

There are a large number of different, partly standardized package structures having different sizes and a different number of leads. They enable standardized manufacturing of printed circuit boards as well as automatic component insertion on printed circuit boards.

These packages additionally have the advantage that a connecting lead arrangement led to the exterior by the chip pads enables improved handling of the chip in a subsequent mounting process.

Dependent upon the number of leads necessary, these packages correspond to a standard having specified dimensions so as to enable a standardized production of printed circuit boards as well as automatic component insertion on printed circuit boards.

The dimensions of these packages are specified in German and international standards.

The reliability of an SMD soldered onto a substrate is substantially affected if the thermal coefficient of expansion of the semiconductor elements differs appreciably from that of the substrate. Different thermal expansion behavior of substrate and components causes high shear forces at the soldered connections, which may lead to cracks in the latter at a later stage.

This problem is not as serious in the case of semiconductor elements in gull-wing packages since the leads then serve as flexible intermediate members between substrate and component, which are capable of compensating for stresses.

This problem is much more serious, however, in flat pack surface-mounted devices.

Flat pack integrated chips are integrated circuits having a very flat structure, wherein a carrier, customarily of a ceramic material, is provided, besides the actual functional element (semiconductor chip), with conductor tracks by means of printing. For the external connection use is made of leads extending in a straight line or in slightly bent form from the package and being cut so as to form short connection stubs. As a result, an electronic component having a very small height is obtained.

In the case of the flat-pack design, the leads are arranged in one plane, which is defined by the side of the package, which, after assembly, faces the printed circuit board or extends parallel thereto.

These leads must be carefully designed to ensure good contact between the semiconductor chip and the substrate accommodating said chip.

EP 0 468 420 discloses an integrated electronic component of flat-pack design with laterally projecting leads, said leads having curled tips.

In the integrated electronic component disclosed in EP 0 468 420, the constructional design of the leads is capable of dealing with thermomechanical stresses at the solder pads under certain conditions only.

Therefore it is an object of the present invention to provide a surface-mounted device comprising a semiconductor chip and leads, wherein the particular design of the pad of the leads precludes the occurrence of cracks in a soldered connection.

In accordance with the invention, this object is achieved by a surface-mounted device comprising a semiconductor chip encapsulated in a package and leads projecting from the package so as to bring the semiconductor chip into contact with a substrate, which leads are provided at their surface, at the location of one of the pads provided for surface mounting, with a three-dimensional contact pattern.

This offers the advantage of an increase of the pad size and, as a result of this surface modification, an improved adhesion between the pad of the leads and the solder.

In accordance with an embodiment of the invention, the three-dimensional contact pattern is provided with recesses.

An embodiment in which the recesses take the form of grooves or holes is preferred.

The contact pattern may comprise recesses having sloping flanks.

In accordance with a particularly preferred embodiment, the contact pattern has recesses with sloping flanks whose mutual distance decreases in the depth direction.

In accordance with a further embodiment of the invention, the recesses having sloping flanks are embodied so as to have a symmetrical sawtooth profile. This embodiment satisfies, in particular, the requirement regarding a thermomechanically low-stress contact. Forces acting on the joint between the leads and the solder are optimally distributed.

As a result of the toothed contact surface of the leads and the solder, movement of leads and substrate with respect to each other is effectively precluded. One of the flanks of the saw teeth always takes up the thermo mechanical stresses. The tensile and shear forces at the pad are converted to compressive forces. As compressive forces do not lead to fatigue of the soldered connections, the service life of the latter is substantially improved.

In accordance with a modification of the invention, the three-dimensional contact pattern is arranged on the main surface of the leads facing the substrate.

In accordance with yet another modification of the invention, the three-dimensional contact pattern is arranged on one of the lateral flank faces of the leads.

In said modification, the mechanical connection is made via the lateral sawtooth action, and the electrical connection is established by means of the smooth main surface of the leads.

These and other aspects of the invention are apparent from and will be elucidated with reference to the embodiment(s) described hereinafter.

In the drawings:

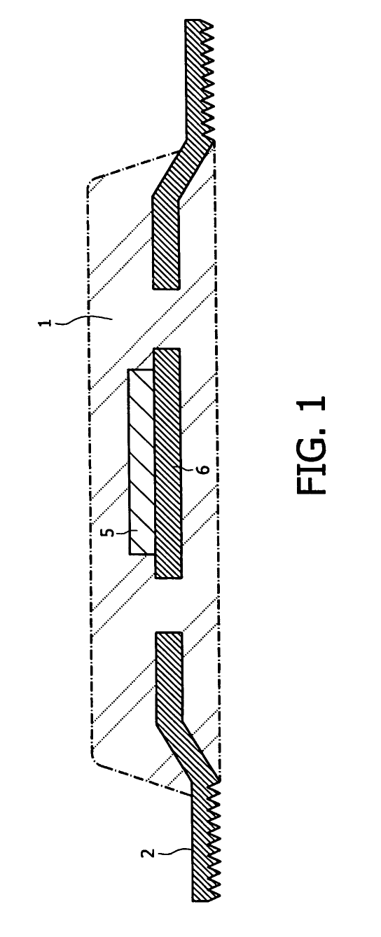

FIG. 1 is a cross-sectional view of a first embodiment of a surface-mounted device in accordance with the invention.

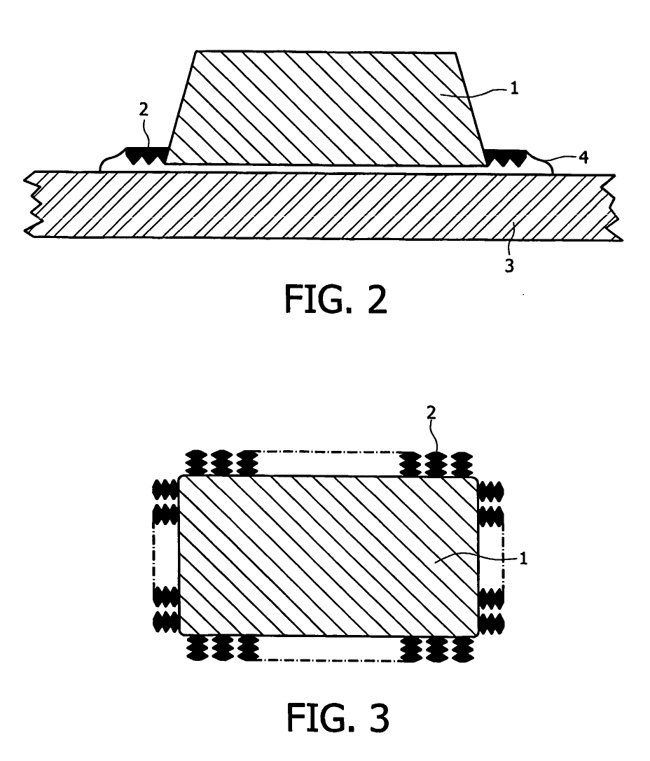

FIG. 2 is a side view of a first embodiment of a surface-mounted device in accordance with the invention.

FIG. 3 is a diagrammatic plan view of a second embodiment of a surface-mounted device in accordance with the invention.

The invention relates to a surface-mounted device in a surface-mounted package (SMP) which is mounted directly on the surface of printed circuit boards or ceramic substrates using SMT technology (surface-mounted technology). SMPs may be used on one side or on both sides of printed circuit boards or in combination with customary leaded components.

The invention particularly relates to a surface-mounted device with a Flat Pack and Quad Flat Pack (QFP) package. These are non-standardized quadratic or rectangular plastic packages for integrated circuits comprising up to more than 100 outward bent leads on two sides (Flat Pack) or on all four sides (QFP).

The surface-mounted device comprises a semiconductor chip mounted on the island of a lead frame, as well as leads connected to the bonding pads of the chip via bonding wires, and a package encapsulating the chip, the island, the bonding wires and the internal end portions of the leads.

The semiconductor chip and the internal leads of the lead frame are fully encapsulated. Only the electrically contactable external end portions of the leads project from the package.

The package has an essentially flat lower side, and the term “lower side” is to be understood to mean herein the surface of the package, which, after assembly on a substrate, faces the latter.

For the semiconductor chip (functional elements) use can be made, for example, of the following non-mass produced component groups: discrete and integrated resistors, capacitors, inductors, sensors, ICs of all types, micro-acoustic and micro-optic ICs and other functional elements. Application takes place in all fields of electronic device technology.

In FIG. 1, reference numeral 1 denotes a package body and reference numeral 2 denotes leads, which are arranged at the four circumferential surfaces of the package body 1 so as to project therefrom. The package body 1 is manufactured so as to be essentially flat by molding a synthetic resin material, the shape of the package body, in plan view, being quadratic or rectangular. The package body encapsulates the internal end portions of the leads. The semiconductor chip 5 is attached to an island 6.

In accordance with the invention, the leads have three-dimensional contact patterns at at least one of the pads. These three-dimensional contact patterns lead to a larger contact area with the solder and to improved anchoring therein.

In accordance with an embodiment of the invention, the three-dimensional contact pattern has recesses. Such a contact pattern is for example obtained without a reduction in cross-section of the leads by an undulation of the leads.

An embodiment wherein the recesses take the form of grooves or holes is preferred.

The contact pattern may comprise recesses with sloping flanks.

In accordance with a particularly preferred embodiment, the contact pattern comprises recesses having sloping flanks, such that the distance between said flanks decreases in the depth direction.

Such recesses are commonly referred to as notches.

Each notch has, for example, two essentially flat side faces and, viewed in cross-section, is for example approximately U or V-shaped. The notches extend perpendicularly across the outer pad of the leads and are open at the two ends facing away from each other.

Viewed in cross-section, the notches may however alternatively be, partly or entirely, arc-shaped and, for example, at most or approximately semi-circular. The term “U-shaped” is understood to include a polygonal shape.

In accordance with an embodiment of the invention, the three-dimensional contact pattern comprises in each case one notch for every lead. In accordance with a preferred embodiment, the three-dimensional contact pattern comprises in each case two notches for every lead.

The three-dimensional contact pattern may also be created by introducing linear structures into the surface of the leads. Particularly suitable are recesses in the form of channels or indentations as they enable comparatively large surfaces to be structured in a specific manner. These channels or indentations may extend parallel to each other.

The contact pattern may alternatively take the form of transverse ribs defining a comb-like cross-section of the flank surface.

The notches may be arranged so as to include an angle in the range of 0 to 90 degrees with the longitudinal axis of the lead. At 0 degrees, the notches extend parallel to the longitudinal axis of the leads. A value in the range around approximately 90 degrees is favorable. If the angle of intersection is chosen to be, for example, 45°, then a favorable transfer of forces is achieved.

In a further embodiment of the invention, the recesses having sloping flanks are embodied so as to form a symmetrical sawtooth profile.

To enhance the resistance to extraction of the soldered connection, it proved advantageous to provide the notches with a sawtooth profile. As a matter of fact, the surface of the part provided with the sawtooth profile is further increased and, as a result, its capability of being anchored in the solder compound is optimized.

In accordance with a modification of the invention, the leads have a contact pattern at the main surface facing the substrate.

As shown in FIG. 3, a three-dimensional contact pattern, for example a sawtooth profile, may be alternatively or additionally provided at at least one of the lateral flank surfaces of the leads.

In this case, the part of the leads provided with the sawtooth-shaped flanks co-operates with the solder in such a manner that the projections of the leads captivate the leads in the soldered connection.

The position and size of the recesses of the contact pattern depend on the size of the package, the power of the semiconductor element (current density, frequency) and the spatial distribution within the package. The position of the contact pattern should be chosen such that the resultant anchoring of the leads precludes delamination at the soldered connection.

Hereinafter, also the manufacture of the surface-mounted device according to the invention is elucidated by means of an example.

First of all a lead frame with a number of islands and associated leads for a number of semiconductor chips is manufactured.

The metallic lead frames which serve for the manufacture of semiconductor elements have a number of conductor tracks (leads) interconnected via stripes, to be removed at a later stage, and a carrier (island) for attaching the semiconductor chip.

The lead frame may be manufactured, in a two-stage etch process, from a starting body of metallic foil in the form of a strip. In the first stage, a unilateral or bilateral etch process is carried out in which etching takes place across the entire thickness of the metal strip. As a result, the desired basic shape of islands, leads and interconnection stripes is obtained.

In the second stage, etching takes place superficially on one side only so as to form the desired three-dimensional contact pattern for the leads.

Various etching processes are known (dry, wet, isotropic, anisotropic, in plasma, chemical etc.) which are all suitable to generate characteristic patterns.

The lead frame may alternatively be manufactured, in a known and customary manner, by punching the starting body from a metal foil present in the form of a strip. Subsequently, as mentioned hereinabove, the details of the contact pattern of the leads and, optionally, of the islands are formed in an etch process.

In addition, there are various other methods of providing or removing three-dimensional contact patterns using mechanical or chemical means. One mechanical surface treatment which deserves particular attention is sand blasting. Sand blasting is an easy-to-use method which yields a satisfactory effect. The surface is substantially enlarged and, in addition, a cramping effect takes place.

Patterning is also advantageously carried out using a laser. By virtue thereof, damage to the lead frame caused by mechanical loads is precluded and a post-cleaning treatment following the patterning operation can be dispensed with.

In a second processing step, the lead frame is bent in a pressing tool. In the bending process, the leads are bent twice and obtain the shape typical of a flat pack package, as shown in FIG. 1.

In the next step, the chip is attached to the island of the lead frame by soldering or gluing.

Next, the bond pads of the chip are electrically connected to the inner pads of the leads by means of bonding wires.

Subsequently, the bonded semiconductor chip is packaged in an injection molding or molding process.

Said packaging operation is, for example, carried out as follows: the bonded semiconductor chip is introduced into an injection mold and surrounded by an injection molding compound in an injection molding process known as transfer molding. The leads of the component, which project, from the package have internal portions, which are embedded in the package in a form-locking manner during encapsulating by injection molding.

After curing of the molded or injection molded compound, the external portions of the leads are punched out, clipped and cleaned.

In accordance with a modification of the manufacturing process, the three-dimensional contact pattern is generated by imprinting notches in the leads after the encapsulation of the semiconductor chip.

The surface-mounted device thus manufactured has a flat lower side. The external pads of the leads extend in the same plane as the lower surface of the package.

To process the surface-mounted devices, any of the known SMD technologies may be employed. The leads of these devices are permanently attached to rigid or flexible substrates by soldering, or optionally by bonding or gluing.

For the soldering process use can be made of a reflow method (reflow soldering) or of other known methods such as, for example, wave soldering using a tin bath.

In the insertion process, the surface-mounted device is provided on the printed circuit board in such a manner that the leads are situated above the solder-coated pads of the printed circuit board. The pads having a three-dimensional contact pattern, which extend parallel to the bearing surface, directly face the solder-coated pads of the printed circuit board. Next, the printed circuit board is fed, in known manner, into a reflow solder oven in which the solder is melted and the leads' pads having a three-dimensional contact pattern are soldered to the pads of the printed circuit board. As shown in FIG. 2, the pads of the leads 2 facing the solder are thus connected to the solder 4 in a form-locking manner. By virtue thereof, a durability of the mechanical and electrical connection between semiconductor component and substrate (printed circuit board) 3 under temperature interaction conditions is achieved which would otherwise be impossible.

1. A surface-mounted device comprising a semiconductor chip encapsulated in a package and leads projecting from the package so as to bring the semiconductor chip into contact with a substrate which leads are provided at their surface, at the location of one of the pads provided for surface mounting, with a three-dimensional contact pattern.

2. A surface-mounted device as claimed in claim 1, characterized in that the three-dimensional contact pattern is provided with recesses.

3. A surface-mounted device as claimed in claim 1, characterized in that the three-dimensional contact pattern has recesses in the form of grooves or holes.

4. A surface-mounted device as claimed in claim 1, characterized in that the three-dimensional contact pattern has recesses with sloping flanks.

5. A surface-mounted device as claimed in claim 1, characterized in that the three-dimensional contact pattern has recesses with sloping flanks whose mutual distance decreases in the depth direction.

6. A surface-mounted device as claimed in claim 1, characterized in that the three-dimensional contact pattern has recesses with a symmetrical sawtooth profile.

7. A surface-mounted device as claimed in claim 1, characterized in that the three-dimensional contact pattern is arranged on the main surface of the leads facing the substrate.

8. A surface-mounted device as claimed in claim 1, characterized in that the three-dimensional contact pattern is arranged on one of the lateral flank faces of the leads.
